(19) United States
(12) Patent Application Publication
(10) Pub. No.: US 2019/0143489 A1
(43) Pub. Date: May 16, 2019

(54) HOLDING DEVICE FOR HOLDING PRINTED CIRCUIT BOARDS AND THE LIKE

(71) Applicant: NOTION SYSTEMS GMBH, Schwetzingen (DE)

(72) Inventors: Jens Münkel, Hockenheim (DE); Jan Schönefeld, Leimen (DE); Michael Doran, Dossenheim (DE)

(21) Appl. No.: 16/189,556

(22) Filed: Nov. 13, 2018

(30) Foreign Application Priority Data
Nov. 14, 2017 (DE) 102017220296.3
Jan. 22, 2018 (DE) 102018200945.7

(51) Int. Cl. B25B 11/00; H05K 3/00

(52) U.S. Cl. CPC B25B 11/005; H05K 2203/013; H05K 2203/0165; H05K 3/0085

(57) ABSTRACT

The invention relates to a holding device for holding substrates such as printed circuit boards, metal sheets, foils or the like, comprising a suction surface, the suction surface having a plurality of suction nozzles and the suction nozzles being subjected to a negative pressure relative to the ambient pressure by means of a device providing negative pressure for providing a holding force for one or more substrates, wherein the device providing negative pressure provides negative pressure, such that the ratio of the cumulated drop in pressure of all suction nozzles to the cumulated drop in pressure of all suction nozzles and supply lines of the suction nozzles up to the device providing negative pressure is greater than 0.25%, in particular greater than 1%, preferably greater than 25%, in particular greater than 35%, preferably greater than 40%.

The invention relates to a holding device for holding substrates such as printed circuit boards, metal sheets, foils or the like, comprising a suction surface, the suction surface having a plurality of suction nozzles and the suction nozzles being subjected to negative pressure relative to the ambient pressure by means of a device providing negative pressure to provide a holding force for one or more substrates.

The invention also relates a method for holding substrates such as printed circuit boards, metal sheets, foils or the like, one or more substrates being held by means of a suction surface, the suction surface comprising a plurality of suction nozzles, and the suction nozzles being subjected to a negative pressure relative to the ambient pressure to provide a holding force for one or more substrates.

The invention further relates to an ink jet printing device.

Printed circuit boards, metal sheets, foils, paper or the like—hereinafter generally referred to as substrates—can have very different degrees of rigidity depending on the area of application and manufacturing procedure. These range from rigid to highly flexible. In addition, substrates often have continuous holes ranging up to extensive openings. For example, printed circuit boards may have holes to be fixed to a carrier by means of a screw connection.

Due to previous processing or their manufacturing process, substrates are often no longer planar, but have deflections in the diagonal direction of several percent, measured as the maximum deviation perpendicular to the diagonal direction at the non-deflected substrate. In order to process these further, it is usual to arrange them on planar processing tables and temporarily determine them in order to allow processing such as printing on the surface of the substrates, cutting, drilling, processing by means of a laser, transporting or automatic optical inspection. During processing, the substrates must be fixed onto the mostly movable and planar processing table in a very reliable way in order to allow precise and fast processing.

For this purpose, the substrates are positioned onto a suction surface of a suction plate in the usual way and held and/or kept onto it by means of negative pressure and/or a suction stream.

A problem in doing so is that areas of a suction surface not covered by the substrate can lead to a collapse of the holding force, i.e. the substrate is no longer adequately kept and/or fixed to the processing table for processing. To solve this problem, it has become common to cover areas of the suction surface not covered by the substrate and areas of openings in the substrate, for example by masking it, to prevent the holding force from collapsing.

In addition, it has become known that the substrates are pulled onto the surface of the processing table at the edges through clamping by means of holding elements, for example in the form of mushroom heads, strips or the like protruding over the surface.

One drawback of this approach is that the areas on both the processing table and the openings in the substrates have to be masked or covered in an elaborate way, which is extremely time-consuming especially with large openings or with a large number of smaller openings. In addition, these have to be removed again in an elaborate way after processing and/or working with the substrate. This creates a certain probability of damaging the processed substrate. In addition, adhesive residues may remain on the suction table, which must be removed in an elaborate way before processing another substrate. Similarly, while processing a substrate, the corresponding covers and/or masks can become detached, resulting in the substrate being incorrectly processed and/or the corresponding processing device being damaged. This increases overall manufacturing costs and reduces the reliability of substrate processing.

One objective of the present invention is therefore to provide a holding device and a method for holding substrates such as printed circuit boards, metal sheets, foils or the like, which allows reliable and easy fixing even of substrates with many and/or large openings and/or with a deflection. A further objective of the present invention is to provide a simple, cost-effective and flexible holder device which allows a faster and/or more efficient processing of substrates.

The present invention achieves in a holding device the objective of holding substrates such as printed circuit boards, metal sheets, foils or the like, comprising a suction surface, the suction surface having a plurality of suction nozzles and the suction nozzles being subjected to a negative pressure relative to the ambient pressure by means of a device providing negative pressure for providing a holding force for one or more substrates, so that the device providing negative pressure provides negative pressure, so that the ratio of the cumulated drop in pressure of all suction nozzles to the cumulated drop in pressure of all suction nozzles and supply lines of the suction nozzles up to the device providing negative pressure is greater than 0.25%, in particular greater than 1%, preferably greater than 25%, in particular greater than 35%, preferably greater than 40%.

The present invention also achieves the objective of a process of holding substrates such as printed circuit boards, metal sheets, foils or the like, with one or more substrates being held by means of a suction surface, the suction surface having a plurality of suction nozzles, and the suction nozzles being subject to a negative pressure relative to the ambient pressure to provide a holding force for one or more substrates, so that a negative pressure is provided by means of the device providing negative pressure, so that the ratio of the cumulated drop in pressure of all suction nozzles to the cumulated drop in pressure of all suction nozzles and supply lines of the suction nozzles up to the device providing negative pressure is greater than 0.25%, in particular greater than 1%, preferably greater than 25%, in particular greater than 35%, preferably greater than 40%.

The present invention also achieves the objective with an ink jet printing device with a holding device according to one of the claims 1-19.

In other words: In order to provide a sufficient holding force for one or more substrates, even in the event that, in particular, one or more or all of them, apart from a suction opening, are not covered by one or more substrates, any suction nozzles covered continue to be subject to a noticeable differential pressure against the ambient pressure. The drop in pressure along the uncovered suction nozzles relative to the drop in pressure up to the vacuum supply device is then dimensioned such that, in the event of all nozzles being uncovered, the drop in pressure at the suction nozzles is sufficiently high to reliably suck in and hold the substrate(s). This limits the maximum leakage stream through uncovered suction nozzles. The more suction nozzles are covered by one or more substrates, the greater the ratio of the cumulated drop in pressure of all suction nozzles to the cumulated drop in pressure of all suction nozzles and supply lines of the suction nozzles up to the device providing negative pressure. In this case, the cumulated drop in pressure at the suction nozzles can be more than 1%, preferably more than 10%, in particular more than 50%, preferably more than 70% in relation to the total drop in pressure up to the device providing negative pressure.

One of the advantages achieved is that additional holding elements in the form of mushroom heads, clamping rails or the like can be dispensed with for holding substrates by means of the holding device. On the one hand, this reduces the time required for processing; time-consuming operation of the holding elements is no longer necessary. In addition, damage to the substrates through the holding elements is avoided, so that a larger substrate surface can be processed, which in turn reduces manufacturing costs for a substrate. A further advantage is that the time-consuming masking and/or covering of open areas of the suction plate and/or substrate can be avoided, which facilitates faster processing of different substrates. Similarly, the accuracy when processing substrates is also significantly increased, since the substrate can be fixed extremely reliably on the one hand, and edge areas can also be reliably processed on the other hand, since the holding elements in the edge area in particular do not cover a part of the substrate surface. This allows the printing distance to be reduced and the printing accuracy to be increased, especially in inkjet printing.

Further features, advantages and other embodiments of the invention are described hereinafter or are thereby disclosed:

According to an advantageous further embodiment at least one of the suction nozzles has a suction opening so that a cross-sectional area of the suction opening is larger than the cross-sectional area of the suction nozzle. In this way, the reliability of providing a holding force for substrates is significantly increased.

According to an advantageous further embodiment, the ratio of the cross-sectional area of the suction openings and the cross-sectional area of the suction nozzles is between 0.01 and 10,000, preferably between 1 and 400, especially between 4 and 144, especially between 25 and 81, preferably between 36 and 64. In this way, the maximum leakage stream through the suction nozzles can be reliably minimised or limited.

According to another advantageous further embodiment, the device providing negative pressure comprises a distribution facility for distributing a suction stream to the suction nozzles. This allows a suction stream to reliably act on the suction nozzles.

In accordance with a further advantageous further embodiment, several suction areas of the suction plate can be separately defined and controlled by means of the distribution facility. One of the advantages is that the efficiency is increased, since on the one hand not needed areas for the suction of substrates can simply be switched off, and on the other hand the reliability of the holding device as a whole is increased, since the leakage stream can be significantly reduced by switching off not needed areas.

According to an advantageous further embodiment, the distribution facility has one or more supply lines for supplying the suction nozzles of the suction surface or of one or more suction areas, with the ratio of the cumulated cross-sectional area of the respective supply lines and the cumulated cross-sectional area of the suction nozzles in the suction surface or in the suction area being at least 0.3, preferably between 1 and 20, in particular between 1.5 and 6 for the suction surface or for each suction area. This ensures reliable admission of the suction stream to the suction nozzles. The supply lines can also have different cross-sections in different areas and thus also have different cumulated cross-sectional areas. For the above ratio, lines in and/or below the suction plate and/or the supply lines to these lines on the basis of the device providing negative pressure can be used.

According to another advantageous further embodiment, the distribution facility has switching valves for controlling different suction areas. Thus, different suction areas can be controlled with one suction stream in a simple and at the same time reliable way.

In accordance with another advantageous further embodiment, the device providing negative pressure has a suction pulse facility, in particular which is arranged between a suction facility and the distribution facility to provide a first suction pulse. The advantage of this is that a time-limited negative pressure pulse can be generated for the first suction of substrates, considerably facilitating the determination of substrates.

According to another advantageous further embodiment, the suction pulse facility has a negative pressure chamber. Thus, a first suction pulse can be provided in a reliable and fast way.

According to another advantageous further embodiment, a facility measuring negative pressure for measuring and regulating a negative pressure of the suction stream and/or a flow measuring facility for measuring the flow through the supply lines is arranged. This allows the pressure of the suction stream to be determined and, if necessary, readjusted. Overall, this allows for substrates to be determined even more reliably by means of the holding device.

According to another advantageous further embodiment, a negative pressure of different suction areas can be measured and regulated by means of the facility measuring negative pressure and/or the flow measuring facility. This also allows the negative pressure to be regulated for different areas, increasing the overall reliability of the substrate holding device.

According to another advantageous further embodiment, a detection device is arranged to detect empty areas of the suction plate which are free of substrates. This allows a fully automated detection and disconnection of unneeded suction areas of the holding device, which considerably simplifies the processing of different substrates.

According to another advantageous further embodiment, the detection facility includes optical and/or acoustic detection means. In doing so empty areas can be flexibly and reliably detected at the same time. Optical detection devices can include cameras, optical sensors or the like. For example, acoustic detection devices can be provided by ultrasonic sensors or the like. Empty areas can also be detected by means of leakage stream measurement and/or negative pressure measurement. This leakage stream measurement can also be combined with optical detection methods to increase the reliability and accuracy of empty area detection.

According to another advantageous further embodiment, the suction nozzles and/or the suction openings are regularly, in particular periodically, arranged. This allows an easy production and at the same time a uniform holding of substrates. The grid of suction openings and/or nozzles can be, for example, between 0.5 mm and 50 mm. In addition to the regular configuration and/or arrangement, a linearly rising or falling grid is also possible.

According to another advantageous further embodiment, essentially adjacent rows of suction nozzles and/or suction openings are arranged offset relation to each other and/or have a different configuration. One of the advantages achieved is that flexibility is increased when holding any irregularly shaped substrates or when placing substrates inaccurately: Substrates with irregular edges with respect to the arrangement of the suction nozzles and/or openings can nevertheless be reliably held and/or fixed by the holding device.

According to another advantageous further embodiment, the suction nozzles and/or the suction openings have a different arrangement density and/or configuration in the edge area of the suction surface. This allows a particularly reliable fixing of substrates in the edge area of the suction surface.

According to another advantageous further embodiment, various suction areas have various arranged and/or configured suction nozzles and/or suction openings. This further increases flexibility when fixing substrates, since substrates of various forms can be reliably held.

In accordance with another advantageous further embodiment, the different suction areas are configured to hold substrates of different rigidity and/or thickness. This makes it possible to determine substrates of different rigidity with regard to deflection in a particularly reliable way. This allows printed circuit boards as well as foils to be reliably and, if necessary, simultaneously fixed onto the suction surface.

Further important features and advantages of the invention result from the sub-claims, from the drawings, and from the corresponding figure description on the basis of the drawings.

It should be understood that the features mentioned above and those still to be explained below can not only be used in the combination indicated, but also in other combinations or in a unique position, without departing from the scope of the present invention.

Preferred versions and embodiments of the invention are shown in the drawings and are explained in more detail in the following description, wherein identical reference numbers refer to identical or similar or functionally identical components or elements.

In this context, the following applies:

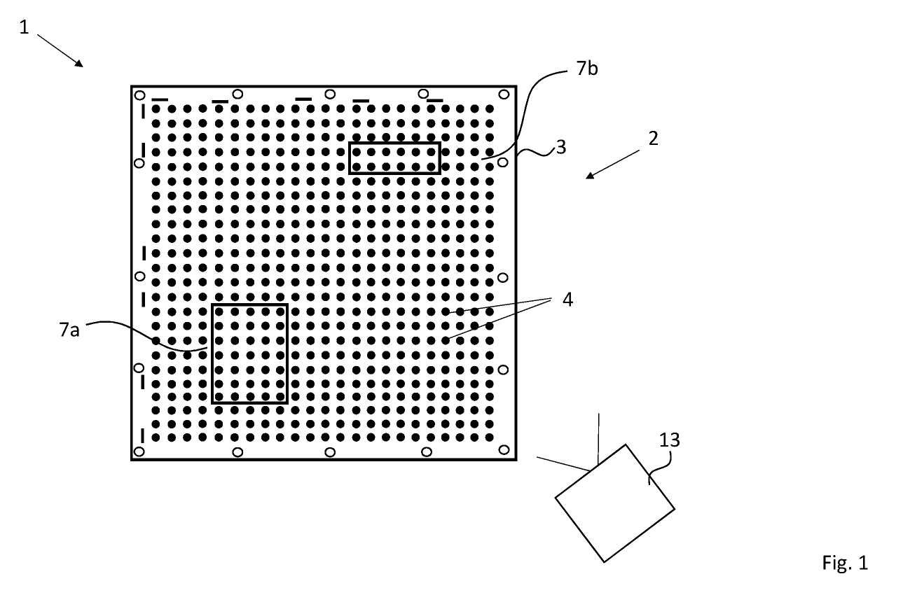

FIG. 1 shows a part of a holding device with a view from above in accordance with an embodiment of the present invention;

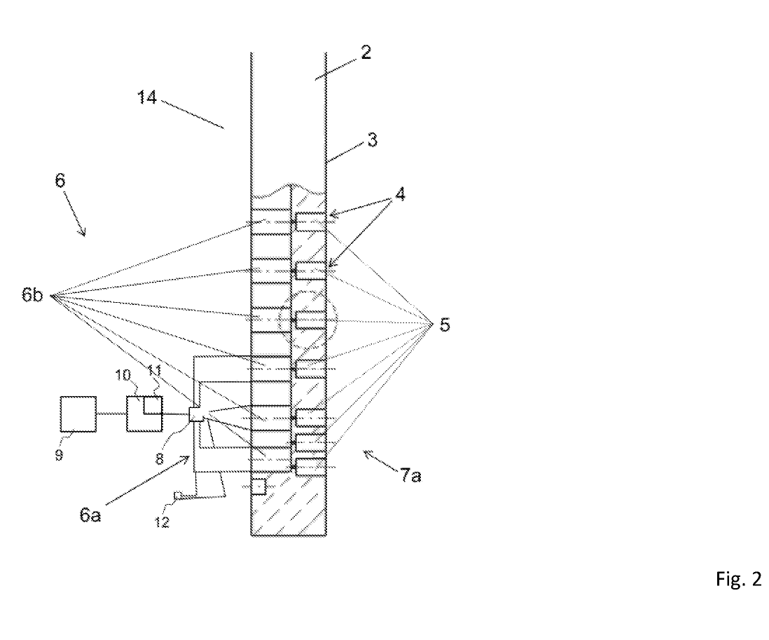

FIG. 2 shows a part of a cross-section through the holding device in accordance with an embodiment of the present invention; and

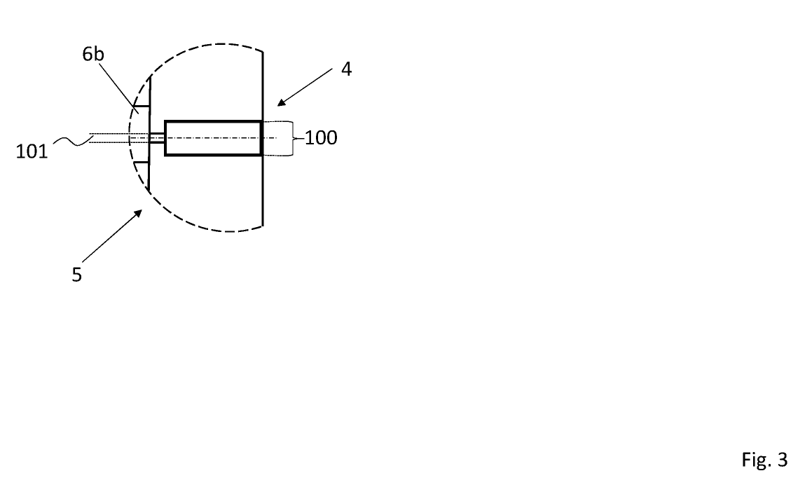

FIG. 3 shows a detailed view of the cross-section of the embodiment in accordance with FIG. 2.

FIG. 1 shows a part of a holding device with a view from above in accordance with an embodiment of the present invention;

FIG. 1 is a holding device 1 shown with a view from above. The holding device 1 has a rectangular negative pressure suction plate 2, which has a suction surface 3 as a substrate. The negative pressure suction plate can also be circular, elliptical or of any other shape. Suction openings 4 are arranged in the suction surface 3 and are periodically or evenly distributed across the suction surface 3. A negative pressure is generated on the upper side of the negative pressure suction plate 2 to hold a substrate arranged on the negative pressure suction plate 2. FIG. 1 also shows examples of suction areas 7a, 7b, which can be separately controlled, and which serve to hold substrates in the respective area 7a, 7b. Suction areas 7a, 7b are essentially freely definable and controllable in their number as well as in their shape and position on the suction surface. For the detection of empty areas on the suction surface 3, i.e. areas on which there is no substrate, a camera 13 can be arranged—as shown here—which is connected to a regulating facility not shown, e.g. a computer, for evaluation, for switching off unoccupied areas of the negative pressure suction plate 2 and for controlling the areas 7a, 7b occupied by substrates. The regulating facility can for example be configured to control the suction facility 9, the distribution facility 6, the suction pulse facility 10 and/or switching valves 8 described in FIG. 2.

For example, the suction openings here have a distance of 10 mm and the suction device 9 provides a negative pressure so that the ratio of cumulated drop in pressure in suction nozzles 5 covered by substrates, which together cover a proportion of the suction surface of approx. 50%, and cumulated drop in pressure of all suction nozzles 5 and supply lines 6a, 6b of the suction nozzles to the suction device 9 is 20%. Depending on this, the same holding force can be achieved by a corresponding proportional change, e.g. by arranging four times the number of suction openings and providing a ratio of cumulated drop in pressure in suction nozzles 5 uncovered by one or more substrates and cumulated drop in pressure of all suction nozzles 5 and supply lines 6a, 6b of the suction nozzles up to suction device 9 of 5% by suction device 9.

FIG. 2 shows a part of a cross-section through the holding device in accordance with an embodiment of the present invention.

In FIG. 2, the negative pressure suction plate 2 is now essentially shown in cross-section. On the right side of the suction plate 2 the suction surface 3 can be seen whereas on the left side of the suction plate 2 there is a supporting surface 14 for supporting the negative pressure suction plate 2 on a supporting structure or similar. Starting from the left side of FIG. 2, a suction device 9, e.g. a negative pressure pump, is schematically shown, which is connected to a suction pulse facility 10 with a negative pressure chamber 11. Further upstream of the suction pulse facility 10, a switching valve 8 is shown, which serves to switch on and off or to control the suction stream for certain suction nozzles 5 for range 7a. FIG. 2 shows only one switching valve 8 as an example; several switching valves can of course be arranged, for example one switching valve per suction nozzle or per supply line. It is also possible to regulate several supply lines 6a or suction nozzles 5 by means of a switching valve 8.

Upstream of the shown switching valve 8 supply lines 6a, 6b of a negative pressure distribution facility 6 are shown. These are used for the fluidic connection of the suction nozzles 5 with the suction facility 9 and are connected to the bottom side 14 of the negative pressure suction plate 2. The supply lines 6a are connected with the supply lines 6b in the negative pressure suction plate 2 and these are connected with the suction nozzles 5. The suction device 9 or the suction pulse facility 10 can each also be configured to provide a temporary compressed air blast. This enables an easy release of a held substrate by temporarily reversing the air flow direction.

For monitoring the negative pressure in the supply lines 6a, 6b a negative pressure measuring facility 12 and/or a flow measuring facility is arranged, which can be connected to the suction facility 9, the suction pulse facility 10 and/or the switching valves 8 for regulation purposes. The cross-section of the supply lines 6a, 6b is selected in such a way that it corresponds to at least twice, and in particular at least three times, the cumulated cross-sectional area of the suction nozzles 5 of the respective subarea 7a, 7b.

FIG. 3 shows a detailed view of the cross-section of the embodiment in accordance with FIG. 2.

FIG. 3 now shows in detail a suction nozzle 5 with connected supply lines 6b in the negative pressure suction plate 2. The ratio of the diameter 100 of the cross-section of the suction opening 4 and the diameter 101 of the cross-section of the suction nozzle 5 is preferably selected between 1 and 20, in particular between 2 and 12, in particular between 5 and 9, preferably between 6 and 8, the ratio of the cross-sectional areas is then between 0.01 and 10,000, preferably between 1 and 400, in particular between 4 and 144, in particular between 25 and 81, preferably between 36 and 64. The limiting cross-section of the respective suction nozzle 5 results in a negative pressure suction stream not collapsing with a partially open surface of the negative pressure suction plate 2, i.e. with areas on which there is no substrate, but remaining essentially constant, the configuration of the cross-section of the suction openings 4 serving to generate the necessary holding force after the suction procedure. In other words: If the cross-sectional area of the suction opening is suitably large, in particular larger than the cross-sectional area of the suction nozzle, the differential pressure is applied to the former. This is advantageous because the holding force for a substrate is essentially proportional to the differential pressure of the suction opening to the ambient pressure and the cross-sectional area of the suction opening.

The suction opening 4 can be part of the suction nozzle 5 or can be configured separately by connecting the suction nozzle 5 with the suction opening 4. In particular, the cross-sectional shape of the suction opening 4 and/or the suction nozzle 5 can be configured cylindrically or elliptically. The suction nozzle 5 with suction opening 4 can be manufactured by means of a bore with a drilling tip and/or with a chamfer.

The suction nozzle can thereby take the form of a small bore or opening with a length of a few millimetres. Alternatively, or additionally, the bore or opening can be replaced or supplemented by a foil, in particular a metal foil, which can be arranged between the distribution facility and the suction openings and which has one or more bores with an even smaller cross-section. A connection between the opening of the suction nozzle and the suction opening can be configured in a funnel-shaped way, i.e. the suction opening runs conically towards a suction nozzle geometry. A porous foil can also be used as an opening for the suction nozzle. Furthermore, the geometry of the suction nozzle(s) can be suitably formed, for example circularly, rectangularly, elliptically or the like.

In summary, the invention and, in particular, at least one of the embodiments can provide or enable the following advantages:
More reliable holding of substrates
easier definition/retention of substrates
lower costs
high efficiency
little effort
high process reliability
high flexibility

The invention can be used in particular in the areas of ink jet printing, laser processing, laser structuring and also for measuring substrates by means of measuring systems, for example camera systems for defect detection on substrates, substrate transport, etc.

Although the present invention has been described using preferred embodiments, it is not limited to these, but can be modified in many ways.

### REFERENCE NUMBERS LIST

1 holding device
2 suction plate
3 suction surface
4 suction opening
5 suction nozzle
6 distribution facility
6a, 6b supply lines
7a, 7b suction areas
8 switching valve
9 suction facility
10 suction pulse facility
11 negative pressure chamber
12 negative pressure measuring device
13 detection facility
100 cross-section of the suction openings
101 cross-section of the suction nozzles

1. A holding device for holding substrates such as printed circuit boards, metal sheets, foils or the like,
comprising
a suction surface, wherein the suction surface has a plurality of suction nozzles and wherein the suction nozzles can be subjected to a negative pressure relative to the ambient pressure by means of a device providing negative pressure for providing a holding force for one or more substrates,
characterised in that,
the device providing negative pressure provides a negative pressure such that the ratio of the cumulated drop in pressure of all suction nozzles and the cumulated drop in pressure of all suction nozzles and supply lines of the suction nozzles to the device providing negative pressure is greater than 0.25%, in particular greater than 1%, preferably greater than 25%, in particular greater than 35%, preferably greater than 40%.

2. The holding device according to claim 1, at least one of the suction nozzles having a suction opening such that a cross-sectional area of the suction opening is larger than the cross-sectional area of the suction nozzle.

3. The holding device according to claim 2, the ratio of the cross-sectional area of the suction openings and the cross-sectional area (101) of the suction nozzles being between 0.01 and 10,000.

4. The holding device according to claim 1, the device providing negative pressure comprising a distribution facility for distributing a suction stream to the suction nozzles.

5. The holding device according to claim 4, several suction areas of the suction plate being separately controllable by means of the distribution facility.

6. The holding device according to claim 4, the distribution facility having one or more supply lines for supplying the suction nozzles of the suction surface or of one or more suction areas, wherein for the suction surface or for each suction area the ratio of the cumulated cross-sectional area of the respective supply lines and the cumulated cross-sectional area of the suction nozzles in the suction surface or in the suction area is at least 0.3.

7. The holding device according to claim 4, the distribution facility having switching valves for controlling different suction areas.

8. The holding device according to claim 7, the device providing negative pressure having a suction pulse facility arranged fluidically between a suction facility and the distribution facility for providing a first suction pulse.

9. The holding device according to claim 8, the suction pulse facility having a negative pressure chamber.

10. The holding device according to claim 1, further including a facility measuring negative pressure and/or a flow measuring facility for measuring the flow through the supply lines is arranged for measuring and regulating a negative pressure of the suction stream.

11. The holding device according to claim 10, a negative pressure of different suction areas measurable and regulated by at least one of means of the facility measuring negative pressure and means of the flow measuring facility.

12. The holding device according to claim 1, a detection facility being arranged for detecting empty areas of the suction plate which are substrate-free.

13. The holding device according to claim 12, the detection facility comprising at least one of a group including optical and and/or acoustic detection means.

14. The holding device according to claim 3, the detection facility being connected to the distribution facility in such a way that, upon detection of empty areas, these can be switched off by means of the distribution facility.

15. The holding device according to claim 1, at least one of the suction nozzles and the suction openings are regularly arranged in a distributed way.

16. The holding device according to claim 15, in which substantially adjacent rows of suction nozzles and/or suction openings are arranged in an offset manner from one another.

17. The holding device according to claim 15, in which, in the edge area of the suction surface, the suction nozzles and/or the suction openings have a different arrangement density.

18. The holding device according to claim 5, various suction areas have various arranged and/or configured suction nozzles and/or suction openings.

19. The holding device according to claim 5, the different suction areas being configured to hold differently rigid and/or differently thick substrates.

20. A method for holding substrates such as printed circuit boards, metal sheets, foils or the like,
wherein one or more substrates are held by means of a suction surface, wherein the suction surface has a plurality of suction nozzles, and wherein the suction nozzles are subjected to a negative pressure relative to the ambient pressure to provide a holding force for one or more substrates,
a negative pressure is provided by means of a device providing negative pressure such that the ratio of the cumulated drop in pressure of all suction nozzles and the cumulated drop in pressure of all suction nozzles and supply lines of the suction nozzles to the device providing negative pressure is greater than 0.25%.

21. An ink-jet printing device with a holding device according to claim 1.
